(19) United States
(12) Patent Application Publication
(10) Pub. No.: US 2011/0157855 A1
(43) Pub. Date: Jun. 30, 2011

(54) INTEGRATED CIRCUITS HAVING LEAD CONTACTS AND LEADLESS CONTACT PADS CONNECTED TO A SURFACE OF A PRINTED WIRING BOARD, AND METHODS FOR CONNECTING THE SAME

(75) Inventor: Deepak K. Pai, Burnsville, MN (US)

(73) Assignee: GENERAL DYNAMICS ADVANCED INFORMATION SYSTEMS, Fairfax, VA (US)

(21) Appl. No.: 13/042,903

(22) Filed: Mar. 8, 2011

Related U.S. Application Data
(62) Division of application No. 12/379,524, filed on Feb. 24, 2009.
(60) Provisional application No. 61/064,337, filed on Feb. 28, 2008.

(51) Int. Cl. H05K 7/00; B23K 31/02; B23K 31/12; B23K 1/20

(52) U.S. Cl. 361/783; 228/155; 228/103

(57) ABSTRACT

A method is provided for connecting an integrated circuit to a surface of a printed wiring board. The integrated circuit includes lead contacts and leadless contact pads. A first solder paste is applied to the leadless contact pads of the integrated circuit, and preformed conductive pieces are placed on the first solder paste. The preformed conductive pieces are slugs that have, for example, a cylindrical shape or a rectangular cross-section. The preformed conductive pieces are heated and brought into electrical contact with the leadless contact pads. The lead contacts are formed into gull wings. The bases of the preformed conductive pieces are generally aligned in a plane, and the bases of the gull wings are substantially coplanar with the plane such that they collectively generally define a contact plane. A second solder paste is applied on the surface, and the bases of the gull wings and the preformed conductive pieces are soldered to the second solder paste on the surface so that the integrated circuit is in electrical contact with the surface through both the leadless contact pads and the lead contacts. The preformed conductive pieces comprise a conductive material (e.g., a copper alloy) that has a higher melting point than the first solder paste and the second solder paste such that the preformed conductive pieces do not melt during heating or soldering that is described above.

### CROSS REFERENCE TO RELATED APPLICATIONS

This application is a divisional of U.S. Utility application Ser. No. 12/379,524 which claims priority to U.S. Provisional Application 61/064,337 filed on Feb. 28, 2008, the disclosure of which is expressly incorporated herein in its entirety.

### BACKGROUND OF THE INVENTION

1. Field of the Invention

The present invention relates to a connection methodology. More specifically, the present invention relates to methodologies for connecting hybrid chips to printed wiring boards where the chips contain both leads and leadless contacts.

2. Discussion of Background Information

An integrated circuit (“IC”) typically comes in two varieties. One variety includes ICs with metal leads extending therefrom that carry power, ground, input and output signal. The metal leads are often rigid and bent into a shape known as a “gull wing.” The other variety uses “leadless” contacts, in which conductive pads are integrated into the surface of the IC. Varieties of methods are known for connecting the leads, leaded ICs, or conductive pads of leadless ICs to printed circuit boards.

Recently a hybrid chip has been introduced that utilizes both gull wing leads and leadless contact pads on the bottom of the chip. FIGS. 1A-1C show an example of such a hybrid chip 102. It is difficult to mount hybrid chip 102 to a printed circuit board, as known connection methodologies for the gull wing and the leadless pads can conflict with each other.

### SUMMARY OF THE INVENTION

According to an embodiment of the invention, a method is provided for connecting an integrated circuit to a surface of a printed wiring board. The integrated circuit includes lead contacts and leadless contact pads. A first solder paste is applied to the leadless contact pads of the integrated circuit, and preformed conductive pieces are placed on the first solder paste. The preformed conductive pieces are slugs that have, for example, a cylindrical shape or a rectangular cross-section. The preformed conductive pieces are heated and brought into electrical contact with the leadless contact pads. The lead contacts are formed into gull wings. The bases of the preformed conductive pieces are generally aligned in a plane, and the bases of the gull wings are substantially coplanar with the plane such that they collectively generally define a contact plane. A second solder paste is applied on the surface, and the bases of the gull wings and the preformed conductive pieces are soldered to the second solder paste on the surface so that the integrated circuit is in electrical contact with the surface through both the leadless contact pads and the lead contacts. The preformed conductive pieces comprise a conductive material (e.g., a copper alloy) that has a higher melting point than the first solder paste and the second solder paste such that the preformed conductive pieces do not melt during heating or soldering that is described above.

In accordance with another embodiment, an apparatus is provided that comprises a printed wiring board having a surface, a plurality of preformed conductive pieces, an integrated circuit comprising a body and leadless contact pads, and a plurality of lead contacts. The lead contacts are formed into gull wings, and attached to the body of the integrated circuit such that they extend laterally away from the body. The preformed conductive pieces comprise a conductive material having a higher melting point than solder paste, and electrically couple the leadless contact pads to the surface of the printed wiring board. The bases of the preformed conductive pieces are generally aligned in a plane, and the base of each of the gull wings is substantially coplanar with the plane. The bases of the gull wings and the bases of the preformed conductive pieces are soldered to the surface of the printed wiring board so that the integrated circuit is in electrical contact with the surface through both the leadless contact pads and the lead contacts. Because the conductive material of the preformed conductive pieces has a higher melting point than solder paste, the preformed conductive pieces do not melt when soldered onto the surface of the printed wiring board and more reliable electrical and mechanical contact can be made between the preformed conductive pieces and the surface of the printed wiring board.

Other exemplary embodiments and advantages of the present invention may be ascertained by reviewing the present disclosure and the accompanying drawings.

### BRIEF DESCRIPTION OF THE DRAWINGS

The present invention is further described in the detailed description which follows, in reference to the noted plurality of drawings by way of non-limiting examples of certain embodiments of the present invention, in which like numerals represent like elements throughout the several views of the drawings, as follows.

FIGS. 1A-1C are top, side and bottom views of a hybrid integrated circuit with leads and leadless contacts in which the leads have been bent into gull wings.

FIG. 2 is a side view of the steps of an embodiment of the invention for attaching a hybrid chip to a printed wiring board.

FIG. 3 is a flow chart of the process steps of FIG. 2.

FIG. 4 is a side view of the steps of an embodiment of the invention for attaching a hybrid chip to a printed wiring board.

FIG. 5 is a flow chart of the process steps of FIG. 4.

FIG. 6 is a side view of the steps of an embodiment of the invention for attaching a hybrid chip to a printed wiring board.

FIG. 7 is a flow chart of the process steps of FIG. 6.

FIG. 8 is a side view of the steps of an embodiment of the invention for attaching a hybrid chip to a printed wiring board.

FIG. 9 is a flow chart of the process steps of FIG. 8.

### DETAILED DESCRIPTION OF EXEMPLARY EMBODIMENTS

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

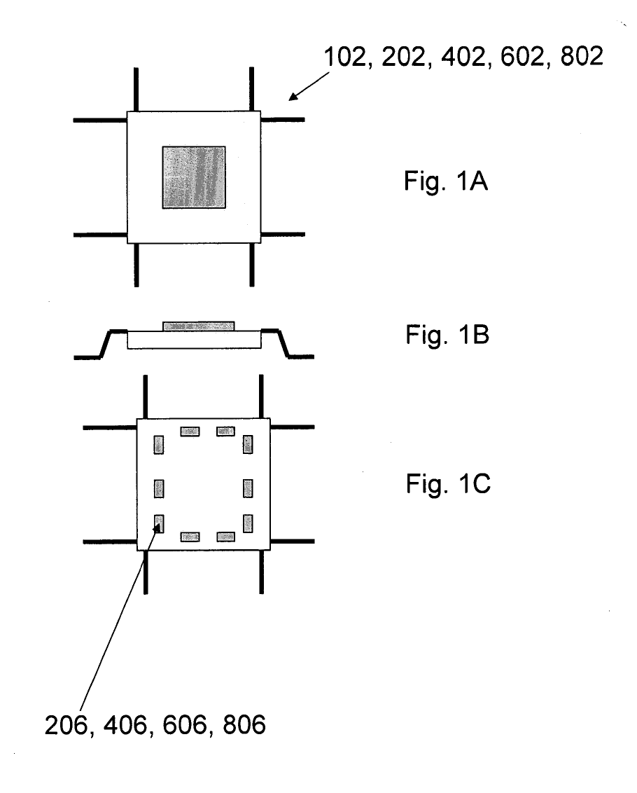

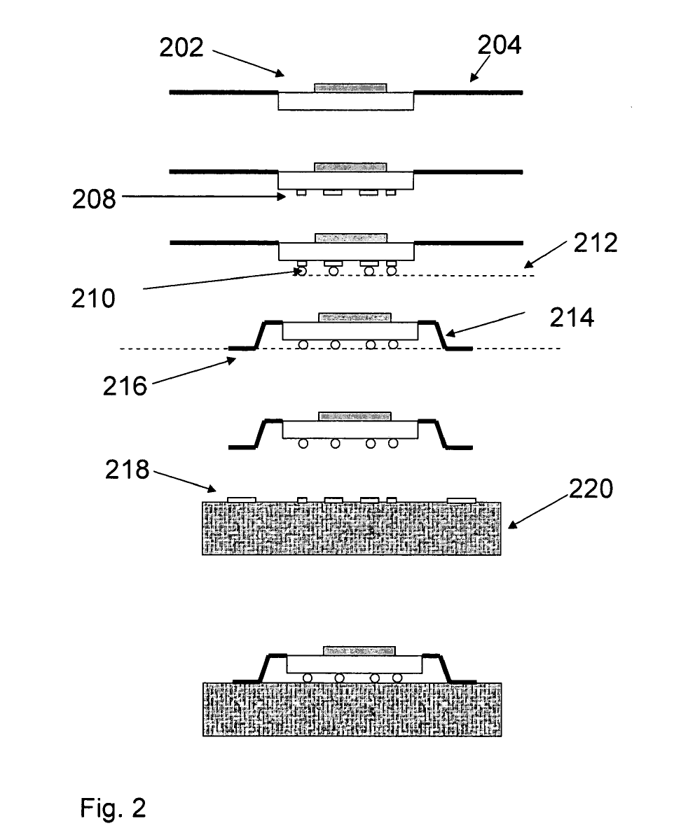

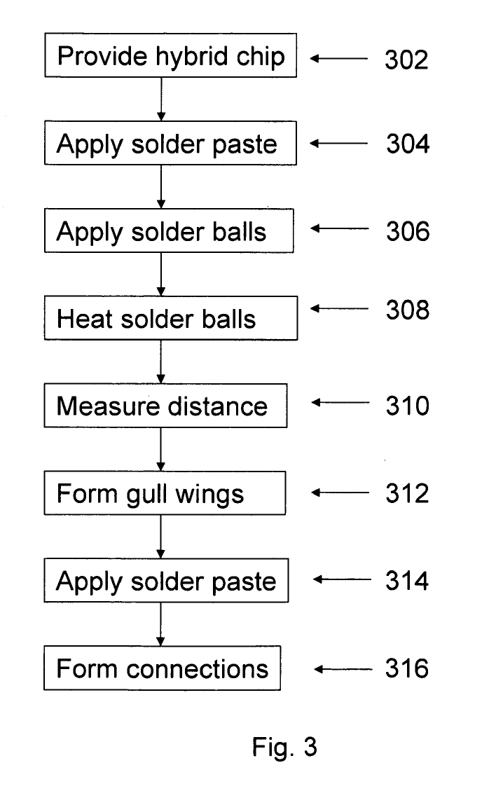

Referring now to FIGS. 2 and 3, a methodology for attaching a hybrid chip 202 is shown. At step 302, a hybrid chip 202 is provided that includes a plurality of leads 204 in a first orientation and a plurality of contact pads 206 (FIG. 1C). The initial orientation (for this embodiment and the later embodiments below) is preferably a connection to the body of chip 202 and extending laterally away from chip 202 without bends. However, other initial orientations may be used.

Solder paste 208 (thickness exaggerated for illustration) is applied to conductive contact pads 206 at step 304. At step 306, solder balls 210 are then applied on top of solder paste 208. The solder balls 210 are then heated to bond with conductive pads 206 at step 308; this tends to remove solder paste 208, such that it is no longer shown in FIG. 2.

Each solder ball 210 is preferably about 10 mils in diameter when deposited, although they are expected to expand as solder flows during soldering. Each solder ball 210 is preferably made from a material with a melting point of 290 degrees or above. Pure copper or a 10/90 alloy of tin and lead are suitable for this environment.

The lower surface of the solder balls 210 will roughly define a base plane 212 at which the solder balls 210 will later connect to a printed wiring board. At step 310 the distance between that plane and leads 204 is then determined, and at step 312 the leads 204 are bent into a second orientation that includes gull wings 214. The lateral wing portions 216 of gull wings 214 lie in the base plane 212, thus forming a collective contact plane.

At step 314, solder paste 218 is applied using a stencil at the appropriate locations on a printed wiring board 220. At step 316, wings 214 are then soldered onto their respective portions of solder paste 218, while the solder balls 210 are heated to form connections onto the printed circuit board 220. The connections at step 316 can be simultaneously or in any order.

Solder balls 210 tend to have minimal compliancy and tend to crack under stress. The connections of FIG. 2 are thus preferable for environments with minimal thermal expansion and/or minimal thermal expansion cycles.

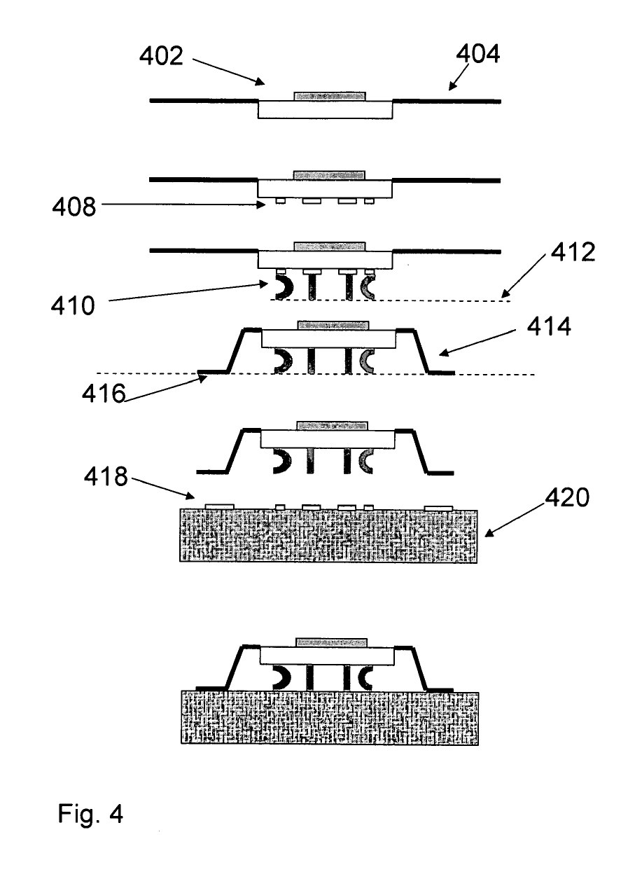

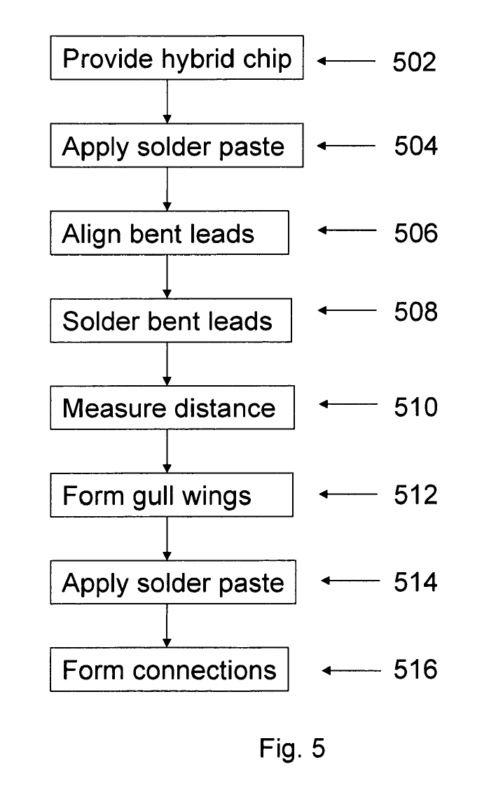

FIGS. 4 and 5 show another embodiment of the invention. At step 502, a hybrid chip 402 is provided that includes a plurality of leads 404 in a first orientation and a plurality of contact pads 406 (as in FIG. 1C). Solder paste 408 (thickness exaggerated for illustration) is applied to contact pads 406 at step 504. At step 506, a plurality of pre-bent conductive leads 410, such as copper alloy C-leads or S-leads, are then secured in fixtures and pressed against solder paste 408. Solder is then applied to connect the bent leads 410 to pads 406 at step 508. Once bent leads 410 are attached, the connection to the securing fixture can be removed.

Each bent lead is preferable 0.40 mils high, and made from a copper alloy. In the alternative, small form factor bent leads of the type shown in co-pending U.S. patent application Ser. No. 11/979,487 (filed on Nov. 7, 2007, the disclosure of which is herein incorporated by reference in its entirety) can be used.

The lower portion of the connected bent leads will roughly define a base plane 412 at which the bent leads 410 will later contact the printed wiring board. At step 510 the distance between that plane and leads 404 is then determined, and at step 512 the leads 404 are bent into a second orientation that includes gull wings 414. The wing portions 416 of gull wings 414 lie in the base plane 412, thus forming a collective contact plane.

At step 514, solder paste 418 is applied using a stencil at the appropriate locations on a printed wiring board 420. At step 516, wings 414 and leads 410 are then soldered onto their respective portions of solder paste 218. The connections at step 516 can be made simultaneously or in any order.

Bent leads have a compliancy that allows them to shift during thermal stress. This makes the connection of FIG. 4 particularly useful for harsh environments subject to considerable thermal expansion and/or repeating thermal expansion cycles.

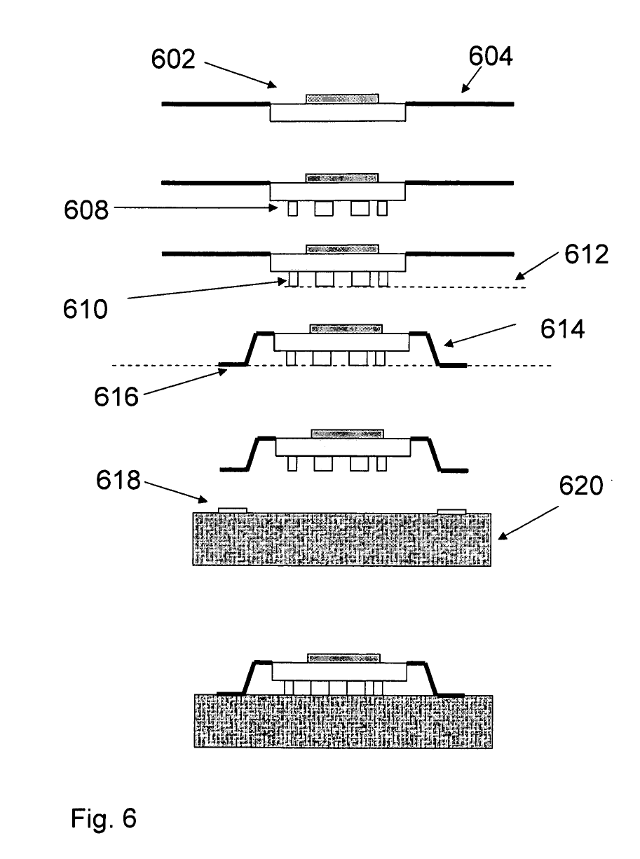

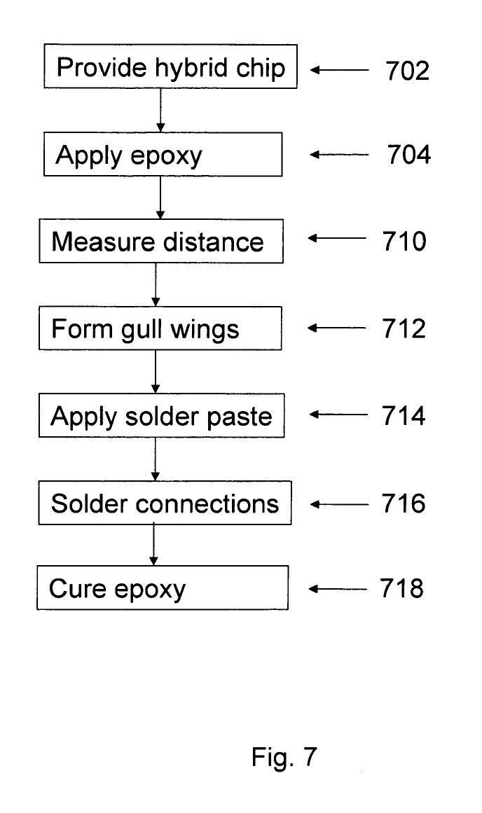

FIGS. 6 and 7 show another embodiment of the invention. At step 702, a hybrid chip 602 is provided that includes a plurality of leads 604 in an initial orientation and a plurality of contact pads 606 (as in FIG. 1C). Conductive epoxy 608 is applied to contact pads 606 at step 704. The lower portion of the epoxy will roughly define a base plane 612 at which the epoxy 608 will later contact the printed wiring board. At step 710 the distance between that plane and leads 604 is then determined, and at step 712 the leads 604 are bent into a second orientation that includes gull wings 614. The wing portions 616 of gull wings 614 lie in the base plane 612, thus forming a collective contact plane.

At step 714, solder paste 618 is applied using a stencil at the appropriate locations on a printed wiring board 420 that correspond to the contact points for wing portions 616. At step 716, wings 614 are soldered onto their respective portions of solder paste 618. At step 718, the epoxy is cured. The connections at steps 716 and 718 can be made simultaneously or in any order.

Conductive epoxy is more compliant than solder but less compliant than bent leads. It is thus suitable for use in environments with moderate to high thermal expansion and/or cycles of thermal expansions, although not to the same extent as bent leads. Thus, for example, this connection methodology is not preferable for avionics applications.

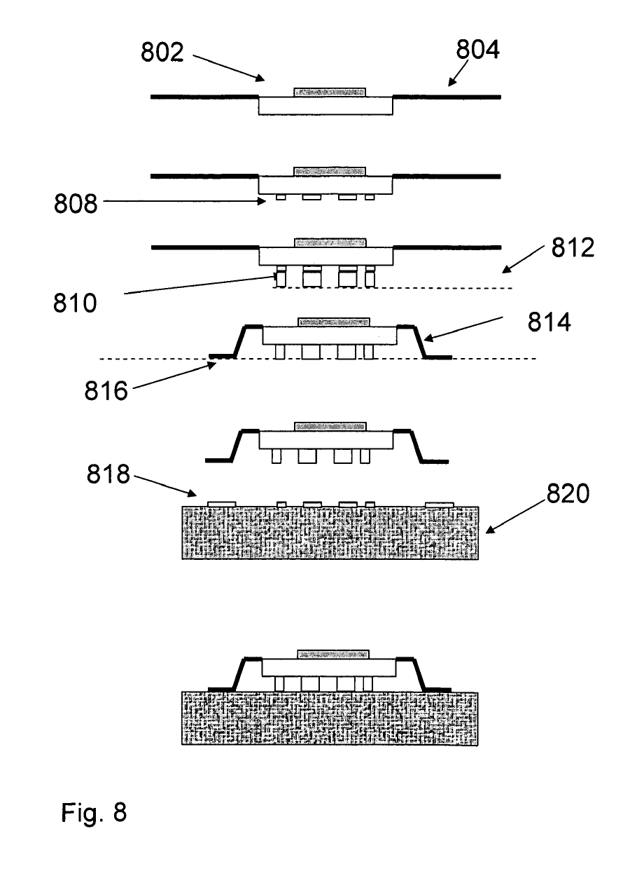

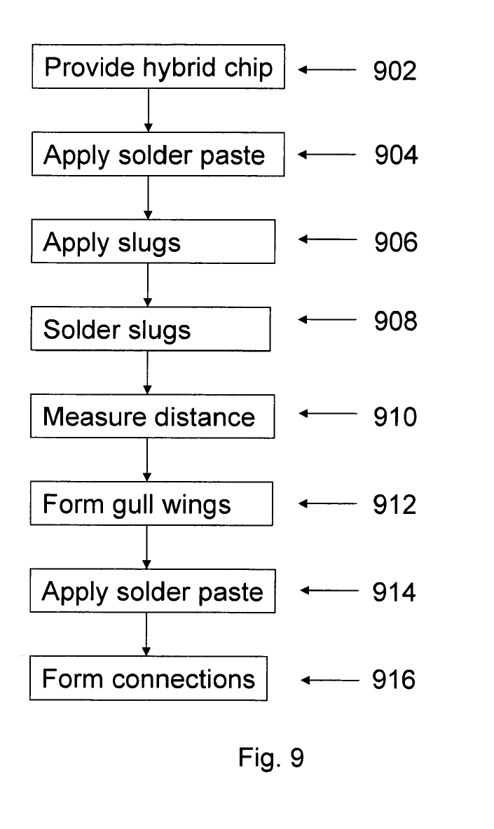

Referring now to FIGS. 8 and 9, another methodology for attaching a hybrid chip 202 is shown. At step 902, a hybrid chip 802 is provided that includes a plurality of leads 804 in an initial orientation and a plurality of contact pads 806 (FIG. 1C). Solder paste 808 (thickness exaggerated for illustration) is applied to contact pads 806 at step 904. At step 906, pre-slugs of conductive metal 810 are then applied on top of solder paste 808. Solder is applied at step 908; this tends to remove the solder paste, such that it is no longer shown in FIG. 8.

Each slug 810 is preferably about 5 mils in height, although other heights could be used. FIG. 8 shows slug 810 as rectangular, but other shapes, such as cylindrical, could be used. Each slug 810 is preferably made from a material with a higher melting point than the solder. A copper alloy with a sufficiently high melting point so as not to melt during the soldering process is sufficient for this.

The lower portion of the slugs 810 will roughly define a base plane 812 at which the slugs 810 will contact the printed wiring board. At step 910 the distance between that plane and leads 804 is then determined, and at step 912 the leads 804 are bent into a second orientation that includes gull wings 814. The wing portions 816 of gull wings 814 lie in the base plane 812, thus forming a collective contact plane.

At step 914, solder paste 818 is applied using a stencil at the appropriate locations on a printed wiring board 820. At step 916, wings 814 are then soldered onto their respective portions of solder paste 818, while the slugs 810 are heated to form connections onto the printed circuit board 820. The connections at step 916 can be made simultaneously or in any order.

It is noted that the foregoing examples have been provided merely for the purpose of explanation and are in no way to be construed as limiting of the present invention. While the present invention has been described with reference to certain embodiments, it is understood that the words that have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of any current or future claims.

Various claims below recite terms for which the following additional discussion may be relevant. For example:
“base” is a relative term generally referring to the lower ends of structures when in the orientation shown in FIG. 1.
“before” and “after” refer to the order of steps, but do not require (nor exclude) that the identified order of steps follow directly or indirectly via intervening steps.
“lead” is used in the context of a lead of a circuit a circuit, as opposed to the metal Pb.

This does not require nor exclude that the lead may be made of Pb or include Pb.

1. A method for connecting an integrated circuit to a surface of a printed wiring board, the integrated circuit including lead contacts and leadless contact pads, the method comprising:
applying a first solder paste to the leadless contact pads of the integrated circuit;
placing preformed conductive pieces on the first solder paste, wherein the preformed conductive pieces comprise a conductive material;
heating the preformed conductive pieces and bringing the preformed conductive pieces into electrical contact with the leadless contact pads, the bases of the preformed conductive pieces being generally aligned in a plane;
forming the lead contacts into gull wings, the bases of the gull wings being substantially coplanar with the plane;
applying a second solder paste on the surface; and
soldering the bases of the gull wings and the preformed conductive pieces to the second solder paste on the surface so that the integrated circuit is in electrical contact with the surface through both the leadless contact pads and the lead contacts, wherein the conductive material of the preformed conductive pieces has a higher melting point than the first solder paste and the second solder paste such that the preformed conductive pieces do not melt during heating or soldering.

2. The method of claim 1, wherein after soldering the base of the gull wings and the preformed conductive pieces to the second solder paste on the surface, the preformed conductive pieces mechanically contact a least a portion of the second solder paste and electrically contact the surface of the printed wiring board.

3. The method of claim 1, wherein the step of heating the preformed conductive pieces, comprises:
soldering the preformed conductive pieces thereby removing at least a portion of the first solder paste and bringing the preformed conductive pieces into electrical contact with the leadless contact pads, the base of the preformed conductive pieces being generally aligned in a plane.

4. The method of claim 1, wherein the step of forming the lead contacts into gull wings, comprises:
bending the lead contacts into gull wings, the base of the gull wings being substantially coplanar with the plane,
wherein the base of the gull wings and the base of the at least one of the preformed conductive pieces collectively generally define a contact plane.

5. The method of claim 1, wherein the conductive material of the preformed conductive pieces comprises a copper alloy.

6. The method of claim 1, wherein the preformed conductive pieces are slugs having a cylindrical shape.

7. The method of claim 1, wherein the preformed conductive pieces are slugs having a shape having a rectangular cross-section.

8. The method of claim 1, further comprising:
determining, before said bending and after said soldering, a lateral distance between the lead contacts and the base of at least one of the preformed conductive pieces.

9. The method of claim 1, wherein said providing the integrated circuit comprises:
providing an integrated circuit with the lead contacts attached to the body of the integrated circuit and extending laterally away from the body.

10. A method for connecting an integrated circuit to a surface, the integrated circuit including lead contacts and leadless contact pads, the method comprising:
applying a first solder paste to the leadless contact pads;
placing preformed conductive slug pieces on the first solder paste, wherein bases of each of the preformed conductive slug pieces are generally aligned in a plane, and wherein the preformed conductive slug pieces comprise a conductive material and have either a rectangular cross-section or a cylindrical shape;
soldering the preformed conductive slug pieces, thereby removing at least a portion of the first solder paste and bringing the preformed conductive slug pieces into electrical contact with the leadless contact pads, wherein the conductive material of the preformed conductive slug pieces has a higher melting point than the first solder paste such that the preformed conductive pieces do not melt during soldering; and
bending the lead contacts into gull wings, the base of the gull wings being substantially coplanar with the plane;
wherein the base of the gull wings and the base of the at least one of the preformed conductive slug pieces collectively generally define a contact plane.

11. The method of claim 10, wherein the conductive material of the preformed conductive pieces comprises a copper alloy.

12. The method of claim 10, further comprising:
electrically connecting said lead contacts and leadless contact pads to the surface.

13. The method of claim 12, said electrically connecting further comprising:
applying a second solder paste to the surface; and
soldering the base of the gull wings and the preformed conductive slug pieces to the surface;
wherein the integrated circuit will be in electrical contact with the surface through both the leadless contact pads and the lead contacts.

14. The method of claim 10, wherein said providing the integrated circuit comprises:
providing an integrated circuit with the lead contacts attached to the body of the integrated circuit and extending laterally away from the body.

15. An apparatus, comprising:
a printed wiring board having a surface;
a plurality of preformed conductive pieces, wherein the preformed conductive pieces comprise a conductive material having a higher melting point than solder paste;
an integrated circuit comprising a body and leadless contact pads, wherein the preformed conductive pieces electrically couple the leadless contact pads to the surface of the printed wiring board, the bases of the preformed conductive pieces being generally aligned in a plane; and
a plurality of lead contacts attached to the body of the integrated circuit and extending laterally away from the body, wherein the lead contacts are formed into gull wings, and wherein a base of each of the gull wings is substantially coplanar with the plane;
wherein the bases of the gull wings and the bases of the preformed conductive pieces are soldered to the surface of the printed wiring board so that the integrated circuit is in electrical contact with the surface through both the leadless contact pads and the lead contacts.

16. The apparatus of claim 15, wherein the conductive material of the preformed conductive pieces comprises a copper alloy.

17. The apparatus of claim 15, wherein the preformed conductive pieces are metal slugs having a rectangular cross-section.

18. The apparatus of claim 15, wherein the preformed conductive pieces are metal slugs having a cylindrical shape.

19. The apparatus of claim 15, wherein the base of the gull wings and the base of the at least one of the preformed conductive pieces collectively generally define a contact plane.
